(19) United States
(12) Patent Application Publication
(10) Pub. No.: US 2025/0301599 A1
(43) Pub. Date: Sep. 25, 2025

(54) IMMERSION COOLING SYSTEM AND COOLING DEVICE

(71) Applicant: WISTRON CORPORATION, New Taipei City (TW)

(72) Inventors: Yu Jei HUANG, New Taipei City (TW); Yuchuan WU, New Taipei City (TW)

(73) Assignee: WISTRON CORPORATION, New Taipei City (TW)

(21) Appl. No.: 18/795,770

(22) Filed: Aug. 6, 2024

(30) Foreign Application Priority Data
Mar. 22, 2024 (TW) 113110906

(51) Int. Cl. H05K 7/20

(52) U.S. Cl. CPC H05K 7/20263; H05K 7/20236; H05K 7/20772

(57) ABSTRACT

An immersion cooling system and a cooling device are provided. The cooling device includes a cooling module, a heat dissipation fin set, an inlet portion and an outlet portion. The cooling module includes a first cooling channel. The heat dissipation fin set is located on the cooling module. The heat dissipation fin set includes a plurality of fins, and a second cooling channel is formed in the plurality of fins. The inlet portion is provided in the heat dissipation fin set or the cooling module. The outlet portion is provided in the cooling module or the heat dissipation fin set. The first cooling channel, the second cooling channel, the inlet portion and the outlet portion are communicated with each other. With the above structure, the fluid can exchange heat through the cooling module and the heat dissipation fin set.

### CROSS-REFERENCE TO RELATED APPLICATION

This application claims the priority and benefit of Taiwan Patent Application No. 113110906 filed on Mar. 22, 2024, the disclosure of which is hereby incorporated in its entirety by reference herein.

### BACKGROUND

### Technical Field

The present disclosure relates a cooling system, and in particular, to an immersion cooling system and device.

### Related Art

With the rapid development of server performance, a server will produce a large amount of heat energy during operation. In order to avoid heat energy accumulation which will cause poor server operation performance, generally a motherboard in the server is immersed in heat dissipation liquid, the heat dissipation liquid can absorb the heat energy generated by heating elements on the motherboard, and the heat dissipation liquid circulates to the outside of a container of the server for heat exchange.

### SUMMARY

According to an embodiment, a cooling device is provided, which includes a cooling module, a heat dissipation fin set, an inlet portion and an outlet portion. A first cooling channel is formed in the cooling module. The heat dissipation fin set is located on the cooling module. The heat dissipation fin set includes a plurality of fins, and a second cooling channel is formed in the plurality of fins. The inlet portion is disposed to the heat dissipation fin set or the cooling module. The outlet portion is disposed to the cooling module or the heat dissipation fin set. The first cooling channel, the second cooling channel, the inlet portion and the outlet portion are communicated with each other.

According to an embodiment, the heat dissipation fin set includes a partition piece. The partition piece includes a substrate and two containing portions. The containing portion are positioned on two sides of the substrate. A plurality of flow division hole parts are formed in one side of each containing portion. The partition piece is connected to the cooling module. The fins are connected to the partition piece.

According to an embodiment, each fin includes two combination portions and an open hole part communicated with the second cooling channel. Each of the two containing portions is connected to the corresponding combination portion. The open hole part of each fin connects to the flow division hole part of the corresponding containing portion.

According to an embodiment, each fin includes a connecting portion arranged between the combination portions of the fin. The partition piece includes a plurality of accommodation portions disposed on the substrate, and each connecting portion is attached to the corresponding accommodation portion.

According to an embodiment, the cooling module further comprises a bearing plate and a plurality of side walls connected with the bearing plate. The cooling module includes a bottom plate and a plurality of heat dissipation plates disposed on the bottom plate. The heat dissipation plates are disposed among the side walls. A lower-layer fluid collection chamber is formed among the bearing plate and the plurality of side walls and the bottom plate.

According to an embodiment, a communicating hole part is formed in the other side of the containing portion. The cooling module is provided with a connecting hole part formed in the bearing plate, and the connecting hole part corresponds to the communicating hole part and communicates the containing portion with the lower-layer fluid collection chamber.

According to an embodiment, the containing portion of the partition piece and the side walls of the cooling module are respectively provided with the inlet portion and the outlet portion, and the inlet portion and the outlet portion are away from the communicating hole part and the connecting hole part and are disposed on the same side of the cooling device.

According to an embodiment, the containing portion of the partition piece and the side walls of the cooling module are respectively connected to the inlet portion and the outlet portion, and the inlet portion and the outlet portion are respectively disposed on two sides of the cooling device.

According to an embodiment, the partition piece includes a baffle, and the baffle is arranged in the containing portion and divides the interior part of the containing portion into two upper-layer fluid collection chambers.

According to an embodiment, the other side of the containing portion is provided with a communicating hole part communicating with the upper-layer fluid collection chambers. The cooling module comprises a connecting hole part formed in the bearing plate, and the connecting hole part corresponds to the communicating hole part and communicates with one of the upper-layer fluid collection chambers.

According to an embodiment, the inlet portion is provided in the containing portion and communicates with the other upper-layer fluid collection chamber. The inlet portion is adjacent to the communicating hole part and the connecting hole part, and the outlet portion is far away from the communicating hole part and the connecting hole part.

According to an embodiment, an immersion cooling system is provided, which includes a container, a first heat transfer fluid, an electronic element, a cooling device and a second heat transfer fluid. The first heat transfer fluid is contained in the container. The electronic element is positioned in the container. The cooling device is positioned in the container and is in contact with the electronic element. The cooling device includes a cooling module, a heat dissipation fin set, an inlet portion and an outlet portion. A first cooling channel is formed in the cooling module. The heat dissipation fin set is located on the cooling module. The heat dissipation fin set includes a plurality of fins, and a second cooling channel is formed in the plurality of fins. The inlet portion is disposed to the heat dissipation fin set or the cooling module. The outlet portion is disposed to the cooling module or the heat dissipation fin set. The first cooling channel, the second cooling channel, the inlet portion and the outlet portion are communicated with each other. The second heat transfer fluid is contained in the first cooling channel and the second cooling channel.

According to an embodiment, an immersion cooling system is provided, which includes a first container, a first heat transfer fluid, an electronic element, a cooling device, a second container, a second heat transfer fluid, a plurality of connecting pipes and a heat exchange device. The first heat transfer fluid is contained in the first container. The electronic element is positioned in the first container. The cooling device is positioned in the first container and is in contact with the electronic element. The cooling device includes a cooling module, a heat dissipation fin set, an inlet portion and an outlet portion. A first cooling channel is formed in the cooling module. The heat dissipation fin set is located on the cooling module. The heat dissipation fin set includes a plurality of fins, and a second cooling channel is formed in the plurality of fins. The inlet portion is disposed to the heat dissipation fin set or the cooling module. The outlet portion is disposed to the cooling module or the heat dissipation fin set. The first cooling channel, the second cooling channel, the inlet portion and the outlet portion are communicated with each other. The second heat transfer fluid is contained in the second container, the first cooling channel and the second cooling channel. One ends of the connecting pipes are connected to the inlet portion and the outlet portion respectively, and the other ends of the connecting pipes are connected to the second container respectively. The heat exchange device includes a guide pipe, a pump and a heat exchange module. The guide pipe is connected to the pump, the heat exchange module and the first container or the second container.

In conclusion, according to some embodiments, the cooling device is provided with the heat dissipation fin set above the cooling module, so that the second heat transfer fluid flows and exchanges heat through the first cooling channel in the cooling module and the second cooling channel in the heat dissipation fin set.

### BRIEF DESCRIPTION OF THE DRAWINGS

FIG. 1A is a schematic architecture diagram of an immersion cooling system applied to a cabinet according to an embodiment.

FIG. 1B is a schematic architecture diagram of an immersion cooling system applied to a cabinet according to an embodiment.

FIG. 2 is a schematic appearance diagram of an immersion cooling system applied to a water cylinder according to an embodiment.

FIG. 3 is a schematic appearance diagram of a cooling device according to an embodiment.

FIG. 4 is an exploded view of a cooling device from a top perspective according to an embodiment.

FIG. 5 is an exploded view of a cooling device from a bottom perspective according to an embodiment.

FIG. 6A is a side sectional view of a cooling device according to an embodiment, in which a heat dissipation fin set is provided with an inlet portion, a cooling module is provided with an outlet portion, and an arrow is used for indicating the flow direction of fluid.

FIG. 6B is a side sectional view of a cooling device according to an embodiment, in which a cooling module is provided with an inlet portion, a heat dissipation fin set is provided with an outlet portion, and an arrow is used for indicating the flow direction of fluid.

FIG. 7 is an exploded view of a cooling device from a top perspective according to an embodiment, in which an inlet portion and an outlet portion are respectively positioned on two sides of the cooling device.

FIG. 8 is an exploded view of a cooling device from a bottom perspective according to an embodiment, in which an inlet portion and an outlet portion are respectively positioned on two sides of the cooling device.

FIG. 9A is a side sectional view of the cooling device according to the embodiment in FIG. 8, in which a heat dissipation fin set is provided with the inlet portion, a cooling module is provided with the outlet portion, and an arrow is used for indicating the flow direction of fluid.

FIG. 9B is a top sectional view of the cooling device according to the embodiment in FIG. 8, in which a heat dissipation fin set is provided with the inlet portion, a cooling module is provided with the outlet portion, and an arrow is used for indicating the flow direction of fluid.

FIG. 10 is an exploded view of a cooling device from a top perspective according to an embodiment, in which an inlet portion and an outlet portion are respectively positioned on two sides of a cooling module.

FIG. 11 is a side sectional view of the cooling device according to the embodiment in FIG. 10, in which the inlet portion and the outlet portion are respectively positioned on two sides of the cooling module, and an arrow is used for indicating the flow direction of fluid.

FIG. 12 is an exploded view of a cooling device from a top perspective according to an embodiment, in which an inlet portion and an outlet portion are respectively positioned on two sides of a heat dissipation fin set.

FIG. 13 is a side sectional view of the cooling device according to the embodiment in FIG. 12, in which the inlet portion and the outlet portion are respectively positioned on two sides of the heat dissipation fin set, and an arrow is used for indicating the flow direction of fluid.

FIG. 14 is a schematic appearance diagram of a cooling device according to an embodiment.

FIG. 15 is an exploded view of a cooling device according to an embodiment.

FIG. 16 is a side sectional view of a cooling device according to an embodiment, in which a side end of each fin is provided with an outlet portion, a cooling module is provided with an inlet portion, and an arrow is used for indicating the flow direction of fluid.

FIG. 17 is a side sectional view of a cooling device according to an embodiment, in which a heat dissipation device is positioned above a heat dissipation fin set, and an arrow is used for indicating the flow direction of fluid.

FIG. 18 is a side sectional view of a cooling device according to an embodiment, in which a heat dissipation device is positioned on a side end of a heat dissipation fin set, and an arrow is used for indicating the flow direction of fluid.

### DETAILED DESCRIPTION

The terms related to connection described in the following embodiment may be a physical connection, or a direct or indirect connection between physical elements. In order to illustrate this application more clearly, in the figures provided in this application, a first axis X is an X-axis of a three-dimensional coordinate system, a second axis Y is a Y-axis of the three-dimensional coordinate system, and a third axis Z is a Z-axis of the three-dimensional coordinate system.

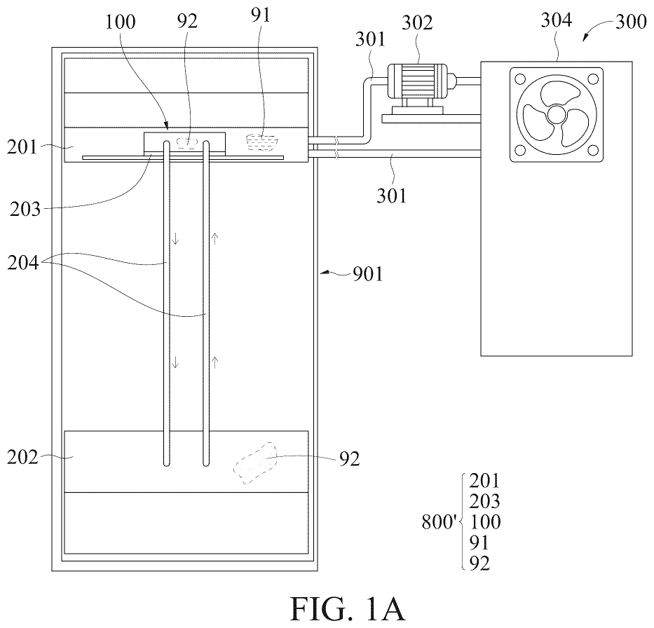

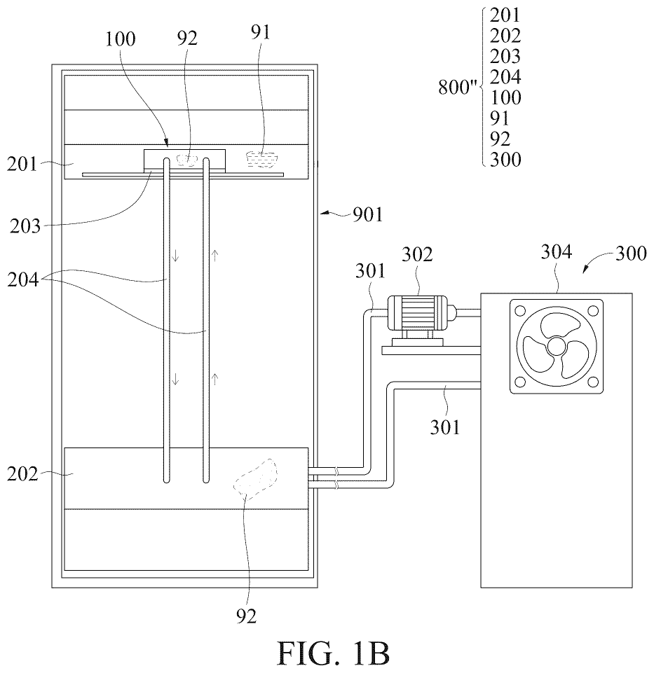

Referring to FIG. 1A, which is a schematic architecture diagram of an immersion cooling system 800′ applied to a cabinet 901, a dotted line block represents a first heat transfer fluid 91, a dot block represents a second heat transfer fluid 92, and a heat exchange device 300 is connected with a first container 201. In some embodiments, the immersion cooling system 800′ is applied to the cabinet 901, and the immersion cooling system 800′ includes a container (hereinafter, the first container 201 is taken an example for explanation) mounted in the cabinet 901, the first heat transfer fluid 91 contained in the first container 201, an electronic element 203 and a cooling device 100. The interior part of the first container 201 is a rectangular closed tank. The first container 201 is a 1U or 2U server chassis, and the height of a standard server takes U as a unit (1U is about 1.75 inches or 44.45 mm). The electronic element 203 is a Central Processing Unit (CPU). The second heat transfer fluid 92 is injected into the cooling device 100. The cooling device 100 is attached above the electronic element 203 for absorbing heat energy dissipated by the electronic element 203.

In this embodiment, the immersion cooling system 800′ further includes a second container 202 and a plurality of connecting pipes 204 mounted in the cabinet 901. The interior part of the second container 202 is a rectangular closed tank. The second heat transfer fluid 92 is contained in the second container 202. One ends of the connecting pipes 204 are connected with the cooling device 100, and the other ends of the connecting pipes 204 are connected to the second container 202. The second heat transfer fluid 92 in the second container 202 is transferred into the cooling device 100 of the first container 201 through the plurality of connecting pipes 204 for heat exchange. In other embodiments, the immersion cooling system 800′ may omit the arrangement of the second container 202 in the cabinet 901, or only needs to arrange a single container in the cabinet 901 for use. The cooling device 100 is arranged in the container, and the container can be the first container 201 or the second container 202.

In some embodiments, the first heat transfer fluid 91 and the second heat transfer fluid 92 are non-conductors, and the first heat transfer fluid 91 and the second heat transfer fluid 92 may be the same or different fluids. The second heat transfer fluid 92 may be a conductive fluid or a non-conductive fluid. When the first heat transfer fluid 91 is the non-conductive fluid, the second heat transfer fluid 92 can be the conductive fluid for use; and the second heat transfer fluid 92 does not make direct contact with the electronic element 203, and is only connected with a loop of the cooling device 100 and the heat exchange device 300.

Referring to FIG. 1B, which is a schematic architecture diagram of an immersion cooling system 800″ applied to the cabinet 901, the heat exchange device 300 is connected with the second container 202. In some embodiments, the immersion cooling system 800″ includes the second container 202, the plurality of connecting pipes 204 and the heat exchange device 300. The interior part of the second container 202 is a rectangular closed tank, and the second container 202 is mounted in the cabinet 901. One ends of the connecting pipes 204 are connected with the cooling device 100, and the other ends of the connecting pipes 204 are connected to the second container 202. The second heat transfer fluid 92 is contained in the second container 202, and the second heat transfer fluid 92 flows into the cooling device 100 through the connecting pipes 204. The heat exchange device 300 includes a guide pipe 301, a pump 302 and a heat exchange module 304. The guide pipe 301 is connected to the pump 302, the heat exchange module 304 and the second container 202, which is not limited thereto. In some embodiments, the guide pipe 301 can also be connected with the first container 201, and the heat exchange device 300 is connected with the first container 201 as shown in FIG. 1A.

The difference between the system architecture in the embodiment in FIG. 1B and the system architecture in the embodiment in FIG. 1A is that the heat exchange device 300 in FIG. 1A is connected with the first container 201, and the heat exchange device 300 in FIG. 1B is connected with the second container 202. In the embodiment in FIG. 1B, the immersion cooling system 800″ further includes the first container 201 mounted in the cabinet 901 and the cooling device 100 located in the first container 201. One ends of the connecting pipes 204 are connected with the cooling device 100, and the other ends of the connecting pipes 204 are connected to the second container 202. The second heat transfer fluid 92 in the second container 202 is transferred into the cooling device 100 through the plurality of connecting pipes 204 for heat exchange.

In view of above, the cooling device 100 is connected with the second container 202 through the connecting pipes 204, and the second container 202 is connected with the heat exchange device 300. When in use, the single second container 202 can be connected with a plurality of first box bodies 201 (illustrated with one first container 201 in FIG. 1B) and the cooling device 100 at the same time, heat in the plurality of first box bodies 201 is taken away through the cooling device 100 and concentrated in the second container 202, and heat exchange is conducted through the heat exchange device 300. Under this configuration, the first box bodies 201 can be used without being connected with the heat exchange device 300.

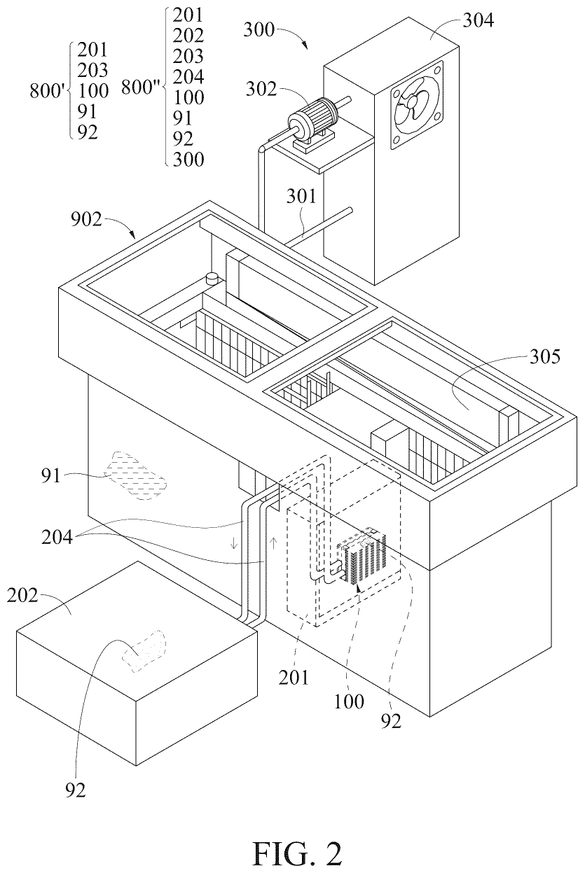

Referring to FIG. 2, which is a schematic appearance diagram of the immersion cooling system 800′/800″ applied to a water cylinder 902, a dotted line block represents the first heat transfer fluid 91, and a point block represents the second heat transfer fluid 92. In some embodiments, the immersion cooling system 800′/800″ is applied to the water cylinder 902 container. The first heat transfer fluid 91 is injected into the water cylinder 902, and the first container 201 immersed in the first heat transfer fluid 91 is arranged in the water cylinder 902. The immersion cooling system 800′/800″ includes a condensation module 305 positioned in the water cylinder 902, and the condensation module 305 is a steam area above the liquid level of the first heat transfer fluid 91. The electronic element 203 (not shown in the figure) and the cooling device 100 are arranged in the first container 201. The second heat transfer fluid 92 is injected into the cooling device 100. The cooling device 100 is attached above the electronic element 203 and used for absorbing heat energy emitted by the electronic element 203.

When the heat exchange device 300 is running, the pump 302 of the heat exchange device 300 circulates heat exchange liquid between the heat exchange module 304 and the condensation module 305 through the guide pipe 301. The condensation module 305 and the cooling fluid thereof have a temperature lower than that of mixed gas phase fluid, for example, a temperature lower than the dew point or the boiling point of working fluid. Therefore, when gas phase working fluid in the mixed gas phase fluid makes contact with the condensation module 305, the gas phase working fluid and the condensation module 305 conduct heat exchange, and the gas phase working fluid is cooled and condensed into liquid phase working fluid and returns to the first heat transfer fluid 91 again.

Referring to FIG. 1B, in some embodiments, when the first heat transfer fluid 91 in the first container 201 above the cabinet 901 in FIG. 1B does not flow, the second heat transfer fluid 92 in the second container 202 below the cabinet 901 can be transferred into the cooling device 100 through the connecting pipes 204 for heat exchange, so that the cooling device 100 is cooled and a heat source of the electronic element 203 below is cooled, and the first heat transfer fluid 91 in the first container 201 is ensured not to be influenced by the heat source of the electronic element 203 to continuously rise the temperature, so as to maintain the temperature of other electronic elements immersed in the first heat transfer fluid 91 in the first container 201. In some embodiments, when the second heat transfer fluid 92 in the second container 202 below the cabinet 901 in FIG. 1B does not flow, the first heat transfer fluid 91 in the first container 201 above the cabinet 901 can be used for heat exchange outside the cooling device 100, so that the cooling device 100 is cooled and the heat source of the electronic element 203 below is cooled.

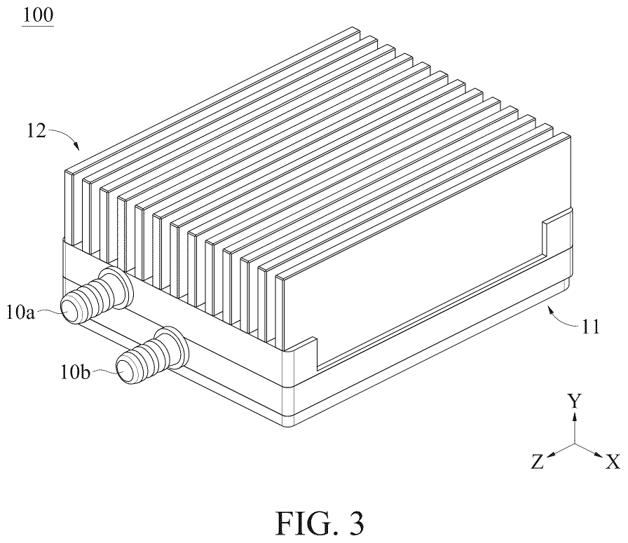

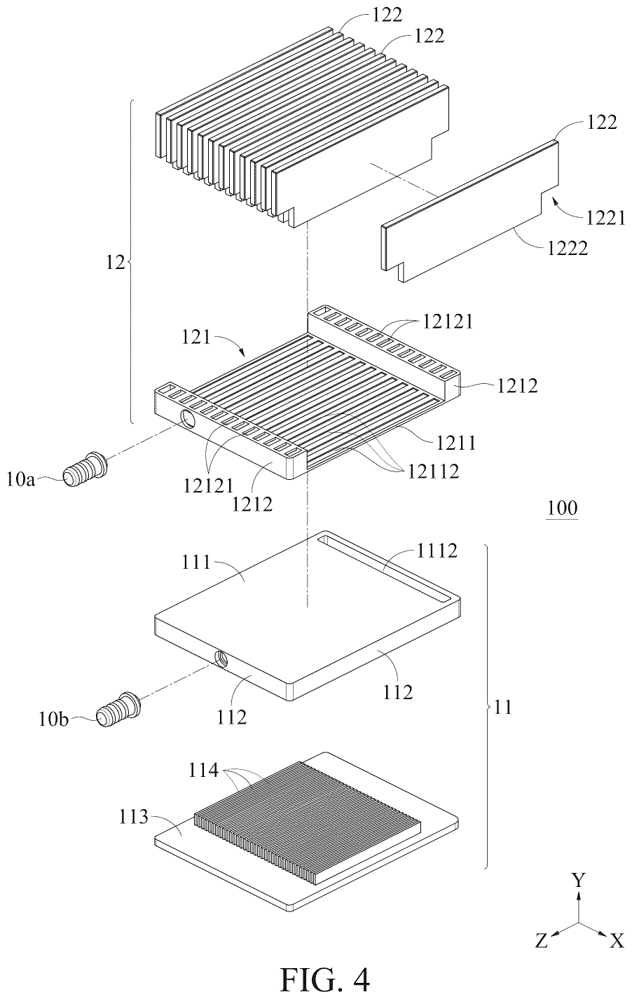

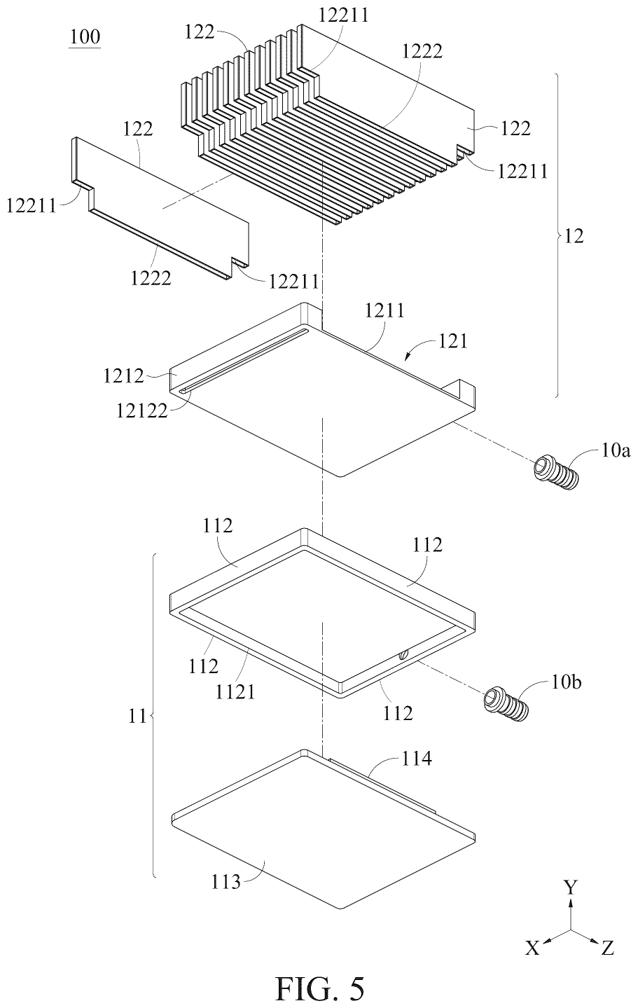

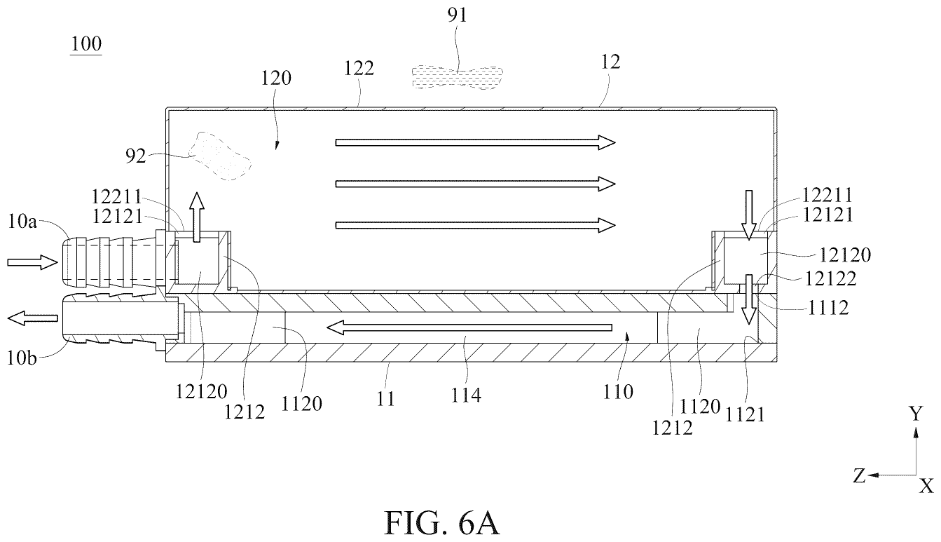

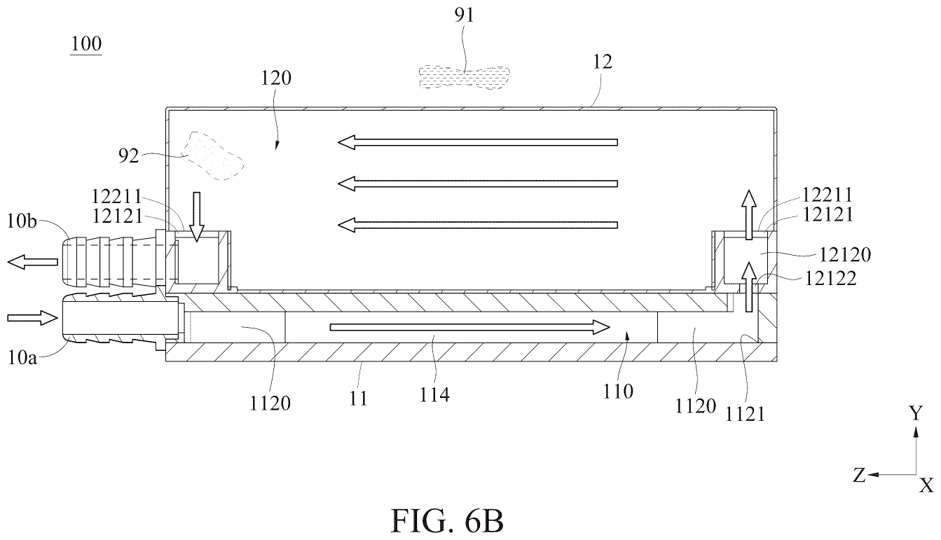

Referring to FIG. 3 to FIG. 6A, FIG. 3 is a schematic appearance diagram of the cooling device 100, FIG. 4 is an exploded view of the cooling device 100 from a top perspective, FIG. 5 is an exploded view of the cooling device 100 from a bottom perspective, and FIG. 6A is a side sectional view of the cooling device 100, in which a heat dissipation fin set 12 is provided with an inlet portion 10a, a cooling module 11 is provided with an outlet portion 10b, and an arrow is used for indicating the flow direction of fluid. The whole cooling device 100 is of a rectangular structure, and the cooling device 100 includes the cooling module 11 (covering plate), the heat dissipation fin set 12 located on the cooling module 11, the inlet portion 10a and the outlet portion 10b. A first cooling channel 110 (such as a water channel) is formed in the cooling module 11. The heat dissipation fin set 12 includes a plurality of fins 122, and a second cooling channel 120 (such as a water channel) is formed in the plurality of fins 122. Each fin 122 is internally provided with a cooling channel. The second cooling channel 120 is formed jointly by the cooling channels in the fins 122. The inlet portion 10a is a water inlet pipe, and the outlet portion 10b is a water outlet pipe. The first cooling channel 110, the second cooling channel 120, the inlet portion 10a and the outlet portion 10b are communicated with each other.

The inlet portion 10a and the outlet portion 10b can be arranged at any position of the cooling device 100 according to requirements, for example, referring to FIG. 6A, the inlet portion 10a is arranged at the heat dissipation fin set 12 at the upper layer, and the outlet portion 10b is arranged at the cooling module 11 at the lower layer, which is not limited thereto. Referring to FIG. 6B, in some embodiments, the inlet portion 10a is arranged at the cooling module 11 at the lower layer, and the outlet portion 10b is arranged at the heat dissipation fin set 12 at the upper layer.

Referring to FIG. 3 to FIG. 6A, in some embodiments, the heat dissipation fin set 12 includes a partition piece 121. The partition piece 121 is connected to the cooling module 11. The fins 122 are arranged at intervals along the direction of a first axis X as shown in FIG. 4. The fins 122 are connected to the partition piece 121. The cooling module 11 and the heat dissipation fin set 12 are fixed through welding.

Referring to FIG. 3 to FIG. 6A, in some embodiments, the partition piece 121 includes a substrate 1211 and two containing portions 1212. Each containing portion 1212 is a rectangular frame body and extends along the direction of the first axis X as shown in FIG. 4. The containing portion 1212 are arranged along the direction of a third axis Z and arranged at two sides of the substrate 1211. The substrate 1211 and the two containing portions 1212 are U-shaped when being viewed from the direction of the first axis X. Each containing portion 1212 is a rectangular frame body extending along the direction of the first axis X; the interior part of each containing portion 1212 is hollow; and an upper-layer fluid collection chamber 12120 (as shown in FIG. 6A) is formed in each containing portion 1212. One side (an upper surface of the containing portion 1212 which can be seen as shown in FIG. 4) of each containing portion 1212 is provided with a plurality of flow division hole parts 12121 communicated with the interior part of each containing portion 1212, and the flow division hole parts 12121 are arranged at intervals along the direction of the first axis X.

Referring to FIG. 3 to FIG. 6A, in some embodiments, each fin 122 is hollow inside and is provided with the second cooling channel 120. The appearance of each fin 122 is generally in a T shape when being viewed from the direction of the first axis X, and each second cooling channel 120 is generally in a T shape when being viewed from the direction of the first axis X as shown in FIG. 6A. Each fin 122 includes two combination portions 1221 and open hole parts 12211. Each combination portion 1221 is a notch and is located at the corners of the bottoms of two ends of the fin 122. The total width of the notches arranged in the direction of the first axis X is smaller than or equal to the total width of the containing portion 1212 extending in the direction of the first axis X. In addition, the open hole parts 12211 are located in the notches in the two ends of the fins 122 and formed in the inner walls in the direction of the third axis Z. The open hole parts 12211 communicate with the second cooling channels 120. The open hole parts 12211 of the fins 122 are aligned with flow division hole parts 12121 in the containing portion 1212 correspondingly.

Referring to FIG. 3 to FIG. 6A, in some embodiments, each fin 122 includes a connecting portion 1222. The connecting portion 1222 is a long protruding block extending in the direction of the third axis Z. Each connecting portion 1222 is arranged between the two combination portions 1221 of the corresponding fin 122. The partition piece 121 includes a plurality of accommodation portions 12112 disposed on the substrate 1211. Each accommodation portion 12112 is a long groove extending in the direction of the third axis Z, and each connecting portion 1222 is attached to the corresponding accommodation portion 12112, so that the corresponding long protruding block can be correspondingly limited in the corresponding long groove, which is not limited thereto. In some embodiments, the accommodation portions 12112 are long protruding blocks, and the connecting portions 1222 are long grooves. When the fins 122 are assembled on the partition piece 121, the containing portion 1212 are limited in the combination portions 1221 on the two sides of the fins 122 respectively. The connecting portions 1222 are correspondingly located on the accommodation portions 12112, and the fins 122 and the partition piece 121 are fixed together through welding.

Referring to FIG. 3 to FIG. 6A, in some embodiments, the cooling module 11 further comprises a bearing plate 111 (such as a flat plate) and a plurality of side walls 112 connected with the bearing plate 111. The cross sections of the bearing plate 111 and the side walls 112 are approximately in an n-shaped appearance when being viewed in the direction of the first axis X. Two opposite side walls 112 of the cooling module 11 extend in the direction of the first axis X as shown in FIG. 5 and are parallel to each other, and two adjacent side walls 112 of the cooling module 11 extend in the direction of the first axis X and extend in the direction of the third axis Z and are adjacent to each other as shown in FIG. 5. In addition, the cooling module 11 includes a bottom plate 113 and a plurality of heat dissipation plates 114 disposed on the bottom plate 113. Each heat dissipation plate 114 is a rectangular sheet extending in the direction of the third axis Z as shown in FIG. 4, and the heat dissipation plates 114 are arranged at intervals in the direction of the first axis X. When the bottom plate 113 covers an opening 1121 (as shown in FIG. 6A) defined by the side walls 112, the heat dissipation plates 114 are disposed among the side walls 112. A lower-layer fluid collection chamber 1120 is formed among the bearing plate 111 and the side walls 112 and the bottom plate 113. The lower-layer fluid collection chambers 1120 are formed in the left side and the right side of the interior part of the cooling module 11 as shown in FIG. 6A.

Referring to FIG. 3 to FIG. 6A, in some embodiments, the other side (a lower surface of the containing portion 1212 which can be seen as shown in FIG. 5) of the containing portion 1212 is provided with a communicating hole part 12122, and the communicating hole part 12122 is a long hole and extends in the direction of the first axis X. The cooling module 11 is provided with a connecting hole part 1112 formed in the bearing plate 111. The connecting hole part 1112 is a long hole and extends in the direction of the first axis X. The connecting hole part 1112 corresponds to the communicating hole part 12122 and communicates the containing portion 1212 with the lower-layer fluid collection chamber 1120.

In some embodiments, the length of the communicating hole part 12122 is equal to that of the connecting hole part 1112, and the width of the communicating hole part 12122 is smaller than that of the connecting hole part 1112, which is not limited thereto.

In some embodiments, the containing portion 1212 of the partition piece 121 and the side walls 112 of the cooling module 11 are respectively provided with the inlet portion 10a and the outlet portion 10b, and the inlet portion 10a and the outlet portion 10b are away from the communicating hole part 12122 and the connecting hole part 1112 and are disposed on the same side of the cooling device 100. The inlet portion 10a as shown in FIG. 4 is arranged at the position, close to the left side, of the left side containing portion 1212, and the outlet portion 10b is arranged at the center of the left side wall 112, so that the inlet portion 10a and the outlet portion 10b are projected to two point positions on the axis of the first axis X and are staggered.

In some embodiments, the containing portion 1212 of the partition piece 121 is provided with the inlet portion 10a, and the side walls 112 of the cooling module 11 are provided with the outlet portion 10b, which are not limited thereto. In some embodiments, the containing portion 1212 of the partition piece 121 can be provided with the outlet portion 10b, and the side walls 112 of the cooling module 11 can be provided with the inlet portion 10a.

When the cooling device 100 performs heat exchange, as shown in FIG. 6A, the second heat transfer fluid 92 enters the second cooling channel 120 from the inlet portion 10a of the cooling device 100, and the second heat transfer fluid 92 enters the second cooling channel 120 of each fin 122 through the containing portion 1212 on the upper layer. At the moment, when the second heat transfer fluid 92 flows into the containing portion 1212 on the left side as shown in FIG. 6A, the second heat transfer fluid 92 turns in the containing portion 1212, changes the flow direction and then flows to the second cooling channel 120 of the heat dissipation fin set 12 at the upper layer, and the flow speed of the second heat transfer fluid 92 at the turning position of the containing portion 1212 is reduced. Then, the second heat transfer fluid 92 flows into the containing portion 1212 on the right side as shown in FIG. 6A from the second cooling channel 120, and then flows downwards to the first cooling channel 110 in the cooling module 11 at the lower layer, and the second heat transfer fluid 92 turns in the lower-layer fluid collection chamber 1120 of the cooling module 11 and changes the flow direction, so that the flow speed of the second heat transfer fluid 92 at the turning position of the lower-layer fluid collection chamber 1120 is reduced. When the second heat transfer fluid 92 flows into the lower-layer fluid collection chamber 1120 on the left side from the lower-layer fluid collection chamber 1120 on the right side as shown in FIG. 6A, the second heat transfer fluid 92 can pass through a slit between the heat dissipation plates 114, and then the second heat transfer fluid 92 flows out from the outlet portion 10b.

In view of above, as shown in FIG. 6A, the second heat transfer fluid 92 is enabled to flow along the U-shaped (seen from the direction of the first axis X) second cooling channel 120 and the first cooling channel 110 which rotate by 90° anticlockwise, so as to take away heat energy (the heat energy of the electronic element 203 in FIG. 1A). Therefore, the second heat transfer fluid 92 flows in the first cooling channel 110 of the cooling module 11 at the lower layer and the second cooling channel 120 of the heat dissipation fin set 12 at the upper layer, thereby being capable of improving the heat dissipation effect.

In some embodiments, when the temperature of the second heat transfer fluid 92 (such as water) in the cooling device 100 is higher than that of the first heat transfer fluid 91 (such as immersion cooling liquid), the cooling device 100 exchanges heat with the external first heat transfer fluid 91 through the heat dissipation fin set 12 at the upper layer, so that the heat dissipation fin set 12 is cooled and the temperature of the second heat transfer fluid 92 is reduced. Then the second heat transfer fluid 92 flows into the cooling module 11 at the lower layer for heat exchange, and the second heat transfer fluid 92 takes away the heat source of the electronic element 203 (not shown in the figure) below the cooling module 11. For example, when the ambient temperature of the first heat transfer fluid 91 is between about 25° C. and 35° C. (such as 27° C., 30° C. or 32° C.), the liquid inlet temperature of the second heat transfer fluid 92 entering from the inlet portion 10a is between about 50° C. and 60° C. (such as 52° C., 55° C. or 57° C.). After the second heat transfer fluid 92 conducts heat exchange in the first cooling channel 110 and the second cooling channel 120 and takes away the heat energy of the electronic element 203, the temperature of the electronic element 203 can be controlled to be between about 55° C. and 65° C. (such as 57° C., 60.5° C. or 62° C.). Therefore, the cooling device 100 is divided into an upper layer and a lower layer for heat exchange, and the effect of enhancing heat dissipation is achieved through good liquid characteristics of the two heat transfer fluids.

Referring to FIG. 6B, FIG. 6B is a side sectional view of the cooling device 100, in which the cooling module 11 is provided with the inlet portion 10a, the heat dissipation fin set 12 is provided with the outlet portion 10b, and an arrow is used for indicating the flow direction of fluid. In some embodiments, when the temperature of the second heat transfer fluid 92 (such as water) in the cooling device 100 is lower than that of the first heat transfer fluid 91 (such as immersion cooling liquid), the inlet portion 10a can be disposed to the cooling module 11 at the lower layer, and the outlet portion 10b can be disposed to the heat dissipation fin set 12 at the upper layer. When the second heat transfer fluid 92 with low temperature enters the cooling module 11 at the lower layer from the inlet portion 10a, the second heat transfer fluid 92 flows in the cooling module 11 and can conduct heat exchange on the high temperature of the electronic element 203, and the second heat transfer fluid 92 flows to the heat dissipation fin set 12 at the upper layer and takes away the heat source of the electronic element 203 (not shown in the figure) below the cooling module 11. For example, when the environment temperature of the first heat transfer fluid 91 is between about 35° C. and 45° C. (such as 37° C., 40° C. or 42° C.), the liquid inlet temperature of the second heat transfer fluid 92 entering from the inlet portion 10a is between about 25° C. and 35° C. (such as 27° C., 30° C. or 32° C.). After the second heat transfer fluid 92 conducts heat exchange in the first cooling channel 110 and the second cooling channel 120 and takes away heat energy of the electronic element 203, the temperature of the electronic element 203 can be controlled to be between about 35° C. and 45° C. (such as 37° C., 40.7° C. or 42° C.).

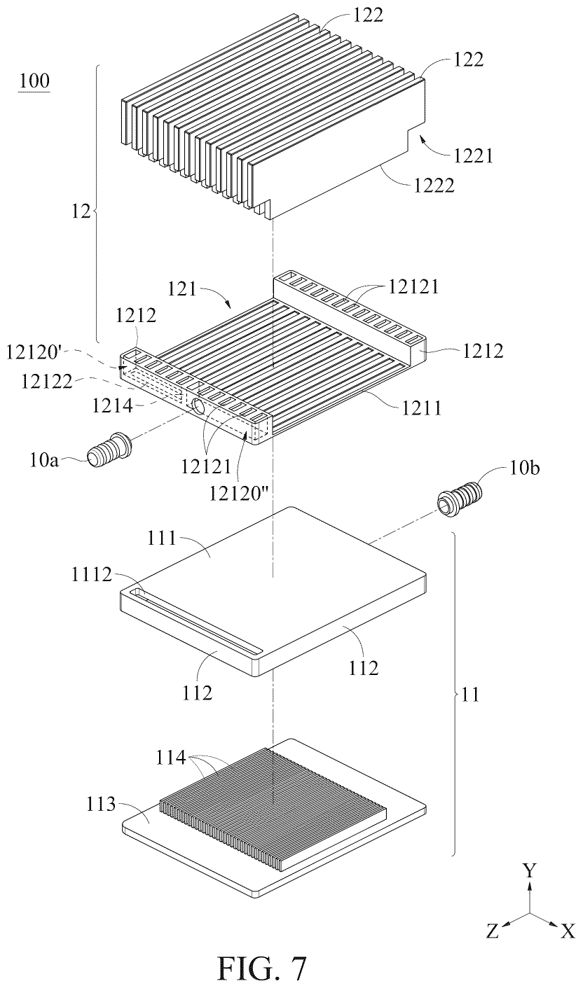

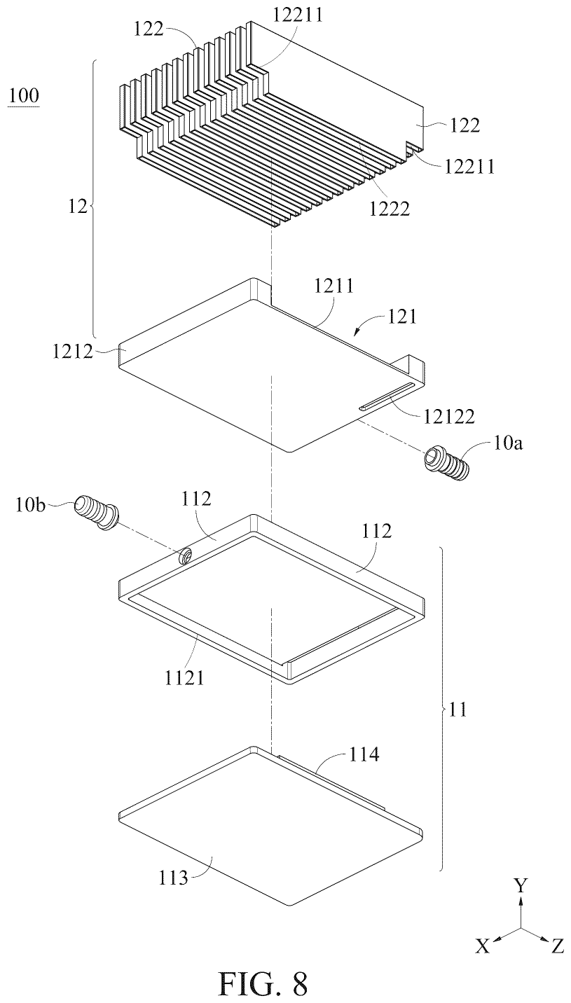

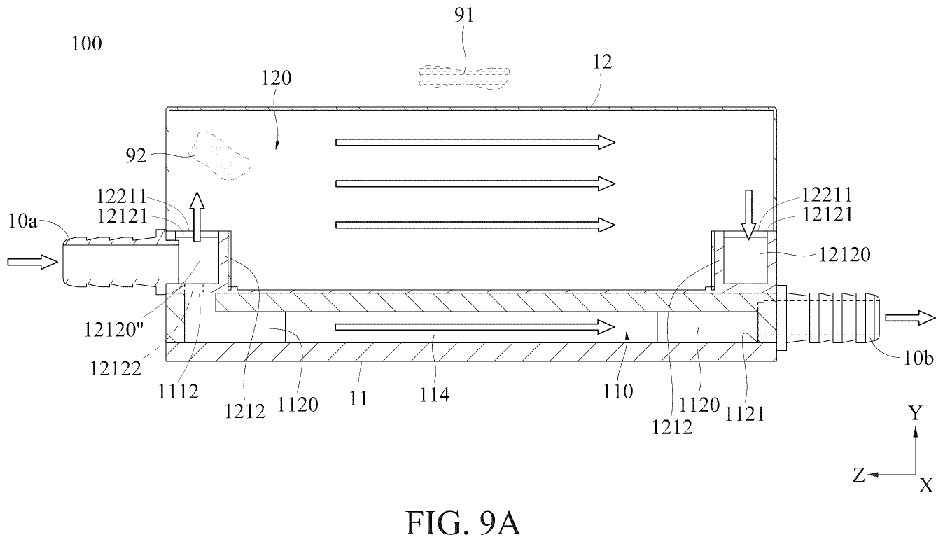

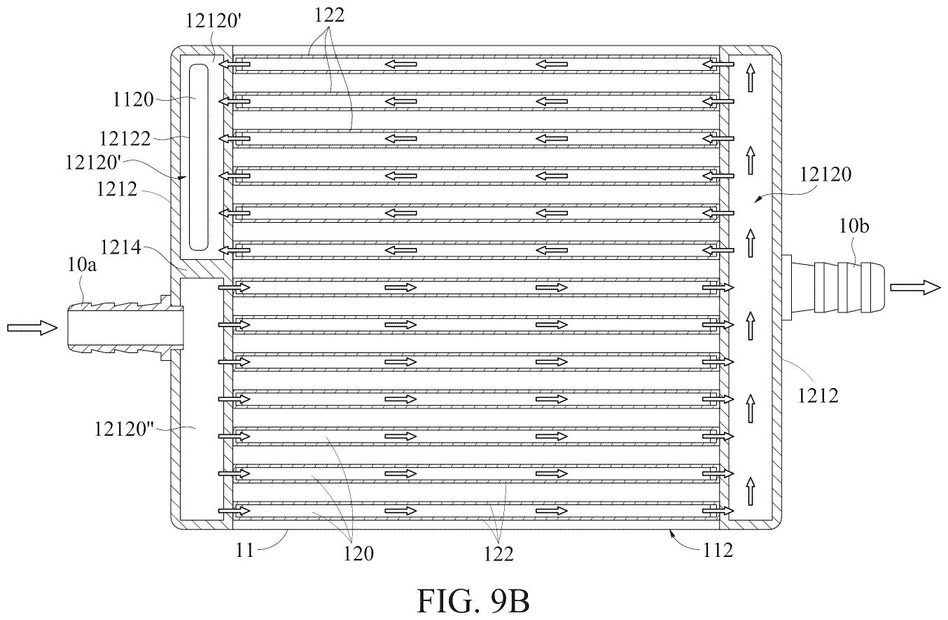

Referring to FIG. 7 to FIG. 9B, FIG. 7 is an exploded view of the cooling device 100 from a top perspective, in which the inlet portion 10a and the outlet portion 10b are respectively positioned on two sides of the cooling device 100; FIG. 8 is an exploded view of the cooling device 100 from a bottom perspective, in which the inlet portion 10a and the outlet portion 10b are respectively positioned on two sides of the cooling device 100; FIG. 9A is a side sectional view of the cooling device 100, in which the heat dissipation fin set 12 is provided with the inlet portion 10a, the cooling module 11 is provided with the outlet portion 10b, and an arrow is used for indicating the flow direction of fluid; and FIG. 9B is a top sectional view of the cooling device 100 according to the embodiment in FIG. 8, in which the heat dissipation fin set 12 is provided with the inlet portion 10a, the cooling module 11 is provided with the outlet portion 10b, and an arrow is used for indicating the flow direction of fluid. In some embodiments, the containing portion 1212 of the partition piece 121 and the side walls 112 of the cooling module 11 are respectively connected to the inlet portion 10a and the outlet portion 10b, and the inlet portion 10a and the outlet portion 10b are respectively disposed on the left side and the right side of the cooling device 100. The partition piece 121 includes a baffle 1214. The baffle 1214 is arranged in the containing portion 1212 on the left side shown in FIG. 7. The baffle 1214 extends in the direction of the third axis Z and divides the interior part of the containing portion 1212 into two upper-layer fluid collection chambers 12120/12120″. The upper-layer fluid collection chamber 12120′ is positioned on the left side of the containing portion 1212 shown in FIG. 7, and the upper-layer fluid collection chamber 12120″ is positioned on the right side of the containing portion 1212 shown in FIG. 7. The two upper-layer fluid collection chambers 12120′/12120″ communicate with the second cooling channel 120 of each fin 122 through the plurality of flow division hole parts 12121.

In some embodiments, the other side (a lower surface of the containing portion 1212 on the left side in FIG. 9A) of the containing portion 1212 comprises the communicating hole part 12122. The cooling module 11 is provided with the connecting hole part 1112 formed in the bearing plate 111. The length of the communicating hole part 12122 is smaller than that of the connecting hole part 1112, and the width of the communicating hole 12122 is smaller than that of the connecting hole part 1112. The connecting hole part 1112 corresponds to the communicating hole part 12122 and communicates with one upper-layer fluid collection chamber 12120′, so as to make the upper-layer fluid collection chamber 12120′ communicate with the interior part of the cooling module 11 through the connecting hole part 1112. Because the containing portion 1212 at the position of the upper-layer fluid collection chamber 12120″ is not provided with the communicating hole part 12122, it does not communicate with the interior part of the cooling module 11.

In some embodiments, the inlet portion 10a is provided in the containing portion 1212 and communicates with the upper-layer fluid collection chamber 12120″. The inlet portion 10a is adjacent to the communicating hole part 12122 and the connecting hole part 1112, and the outlet portion 10b is far away from the communicating hole part 12122 and the connecting hole part 1112, which is not limited thereto. When the second heat transfer fluid 92 enters the upper-layer fluid collection chamber 12120″ from the inlet portion 10a on the containing portion 1212 on the left side shown in FIG. 7, the second heat transfer fluid 92 can flow in through the second cooling channel 120 of each fin 122 below the heat dissipation fin set 12 shown in FIG. 9B. Then the second heat transfer fluid 92 can flow into the containing portion 1212 on the right side shown in the FIG. 9A and then flows in the direction turning to an upward arrow in the containing portion 1212 on the right side shown in FIG. 9B. Then the second heat transfer fluid 92 can flow through the second cooling channel 120 of each fin 122 above the heat dissipation fin set 12 in the left direction, at the moment, the second heat transfer fluid 92 returns to the side of the inlet portion 10a, then sequentially flows through the upper-layer fluid collection chamber 12120′, the communicating hole part 12122 and the connecting hole part 1112 and then enters the cooling module 11 at the lower layer, and passes through the slit between the heat dissipation plates 114 in the cooling module 11 and flows into the outlet portion 10b on the right side shown FIG. 9A and FIG. 9B. Therefore, the second heat transfer fluid 92 flows in the first cooling channel 110 and the second cooling channel 120 of an extending water path, and the heat dissipation effect can be improved.

The inlet portion 10a is provided in the containing portion 1212 and communicates with the upper-layer fluid collection chamber 12120″, which is not limited thereto. In some embodiments, the positions of the inlet portion 10a and the outlet portion 10b can be exchanged, the outlet portion 10b can be provided in the containing portion 1212 and communicates with the upper-layer fluid collection chamber 12120″, the outlet portion 10b is adjacent to the communicating hole part 12122 and the connecting hole part 1112, and the inlet portion 10a can be located on the side wall 112 of the cooling module 11 and is far away from the communicating hole part 12122 and the connecting hole part 1112.

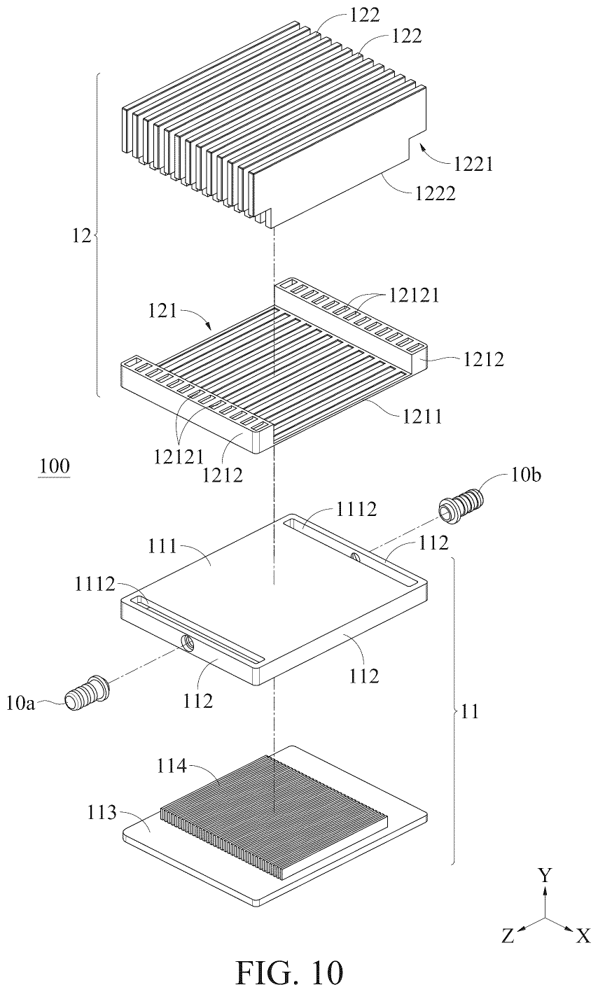

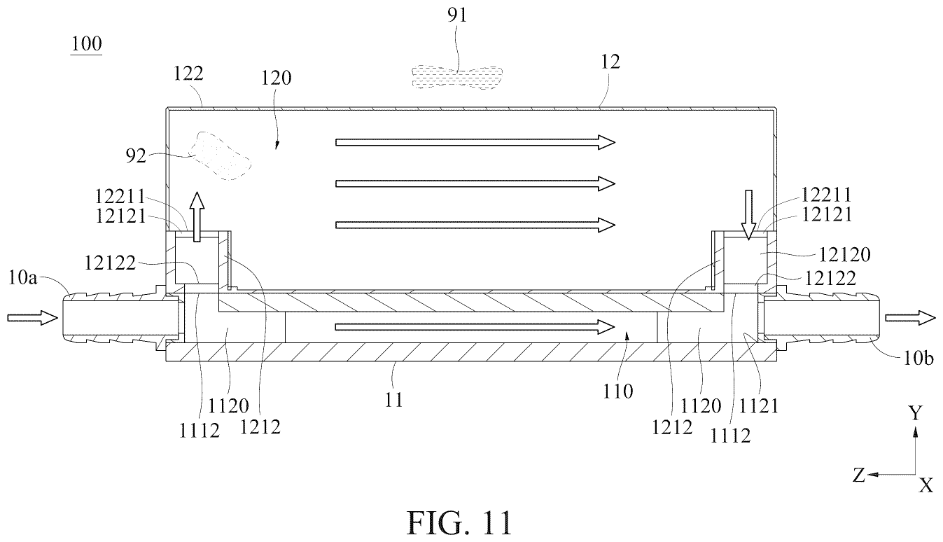

Referring to FIG. 10 and FIG. 11, FIG. 10 is an exploded view of the cooling device 100 from a top perspective, in which the inlet portion 10a and the outlet portion 10b are respectively positioned on two sides of the cooling module 11, and FIG. 11 is a side sectional view of the cooling device 100 according to the embodiment in FIG. 10, in which the inlet portion 10a and the outlet portion 10b are respectively disposed on the two sides of the cooling module 11, and an arrow is used for indicating the flow direction of fluid. In some embodiments, the other side (lower surfaces of the containing portion 1212 on the left and right sides shown in the FIG. 11) of each containing portion 1212 is provided with two communicating hole parts 12122 communicated with the containing portion 1212 respectively. The cooling module 11 is provided with two connecting hole parts 1112 formed in the bearing plate 111. The connecting hole parts 1112 correspond to the communicating hole parts 12122 respectively and communicate with the interior part of each containing portion 1212 and the interior part of the cooling module 11. The communicating hole part 12122 and the connecting hole part 1112 in the left side shown in FIG. 11 are adjacent to the inlet portion 10a on the left side of the cooling module 11, and the communicating hole part 12122 and the connecting hole part 1112 in the right side shown in FIG. 11 are adjacent to the outlet portion 10b on the right side of the cooling module 11.

In some embodiments, the inlet portion 10a and the outlet portion 10b are respectively provided on the two opposite side walls 112 of the cooling module 11, which is not limited thereto. In some embodiments, the inlet portion 10a and the outlet portion 10b can be respectively provided on two adjacent side walls 112 of the cooling module 11.

When the second heat transfer fluid 92 enters the lower-layer fluid collection chamber 1120 on the left side shown in FIG. 11 from the inlet portion 10a, the second heat transfer fluid 92 can be divided to: (1) flow into the containing portion 1212 on the right side shown in FIG. 11 through the second cooling channel 120 of the fin 122 of the heat dissipation fin set 12 at the upper layer, and then flow into the lower-layer fluid collection chamber 1120 on the right side shown in FIG. 11 to the outlet portion 10b from the communicating hole part 12122 and the connecting hole part 1112; and (2) flow through the slit between heat dissipation plates 114 in the cooling module 11 at the lower layer and flow into the outlet portion 10b towards the lower arrow direction shown in FIG. 11.

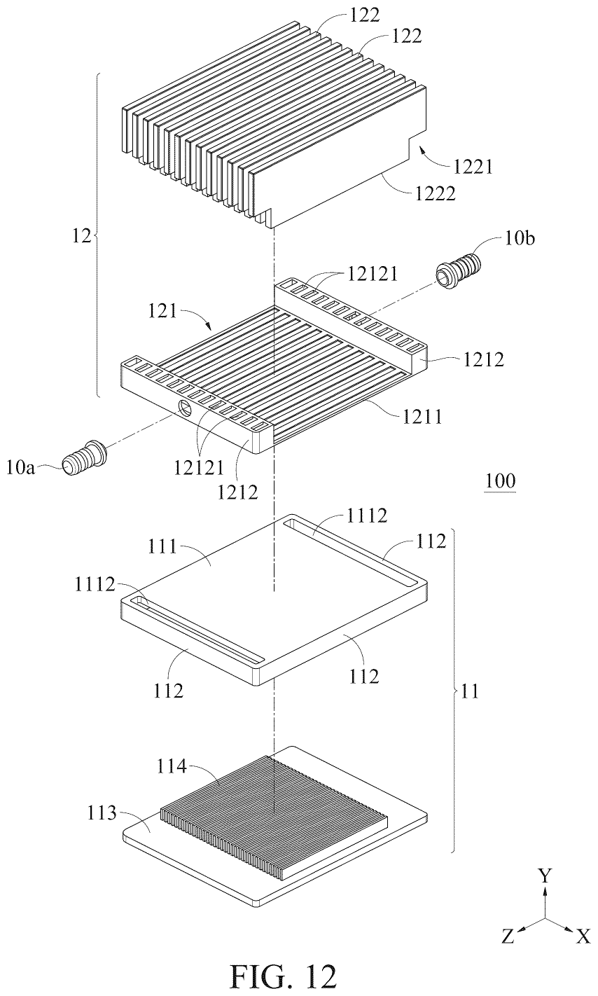

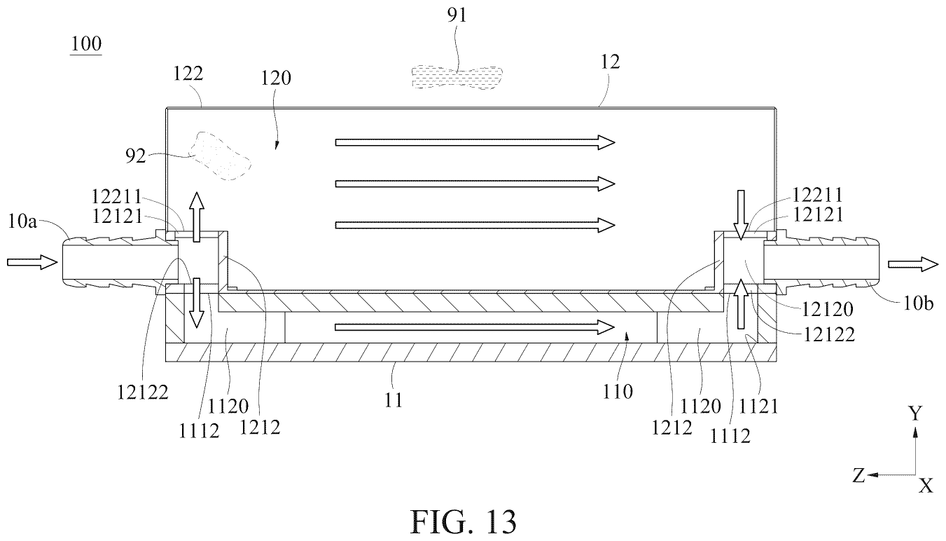

Referring to FIG. 12 and FIG. 13, FIG. 12 is an exploded view of the cooling device 100 from a top perspective, in which the inlet portion 10a and the outlet portion 10b are respectively positioned on two sides of the heat dissipation fin set 12, and FIG. 13 is a side sectional view of the cooling device 100 according to the embodiment in FIG. 12, in which the inlet portion 10a and the outlet portion 10b are respectively disposed on two sides of the heat dissipation fin set 12, and an arrow is used for indicating the flow direction of fluid. In some embodiments, the other side (a lower surface of the containing portion 1212 which can be seen as shown in FIG. 13) of each containing portion 1212 is respectively provided with two communicating hole parts 12122 communicated with the containing portion 1212. The cooling module 11 is provided with two connecting hole parts 1112 formed in the bearing plate 111. The connecting hole parts 1112 correspond to the communicating hole parts 12122 respectively and communicate with the containing portion 1212. The communicating hole part 12122 and the connecting hole part 1112 in the left side shown in FIG. 13 are respectively adjacent to the inlet portion 10a on the left side of the partition piece 121, and the communicating hole part 12122 and the connecting hole part 1112 in the right side shown in FIG. 13 are respectively adjacent to the outlet portion 10b on the right side of the partition piece 121.

In some embodiments, the inlet portion 10a and the outlet portion 10b are respectively disposed on the two sides of the partition piece 121. The inlet portion 10a is provided in the containing portion 1212 on the left side of the partition piece 121 shown in FIG. 13, and the outlet portion 10b is provided in the containing portion 1212 on the right side of the partition piece 121 shown in FIG. 13, which is not limited thereto.

After the second heat transfer fluid 92 enters the containing portion 1212 on the left side shown in FIG. 13 from the inlet portion 10a, the second heat transfer fluid 92 can be divided to: (1) flow into the containing portion 1212 on the right side shown in FIG. 13 through the second cooling channel 120 of the fins 122 of the heat dissipation fin set 12 at the upper layer and then flow into the outlet portion 10b; and (2) flow into the cooling module 11 through the lower-layer fluid collection chamber 1120 on the left side shown in FIG. 13, pass through the slit between the heat dissipation plates 114, flow into the lower-layer fluid collection chamber 1120 on the right side in the arrow direction of the right side shown in FIG. 13, then upwards flow into the containing portion 1212 on the right side and then flow into the outlet portion 10b.

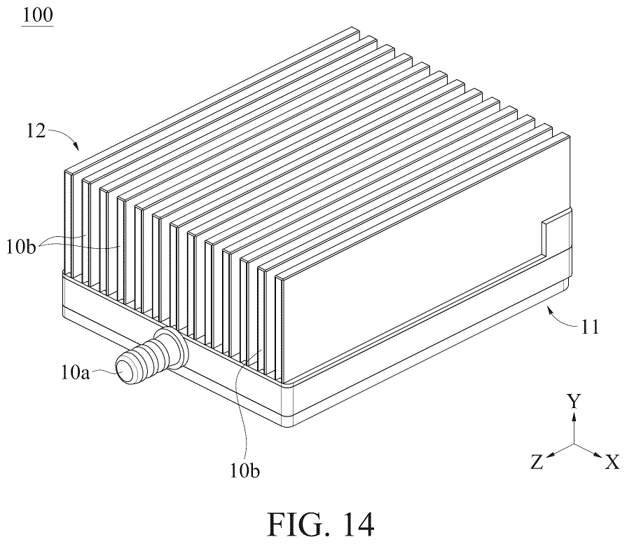

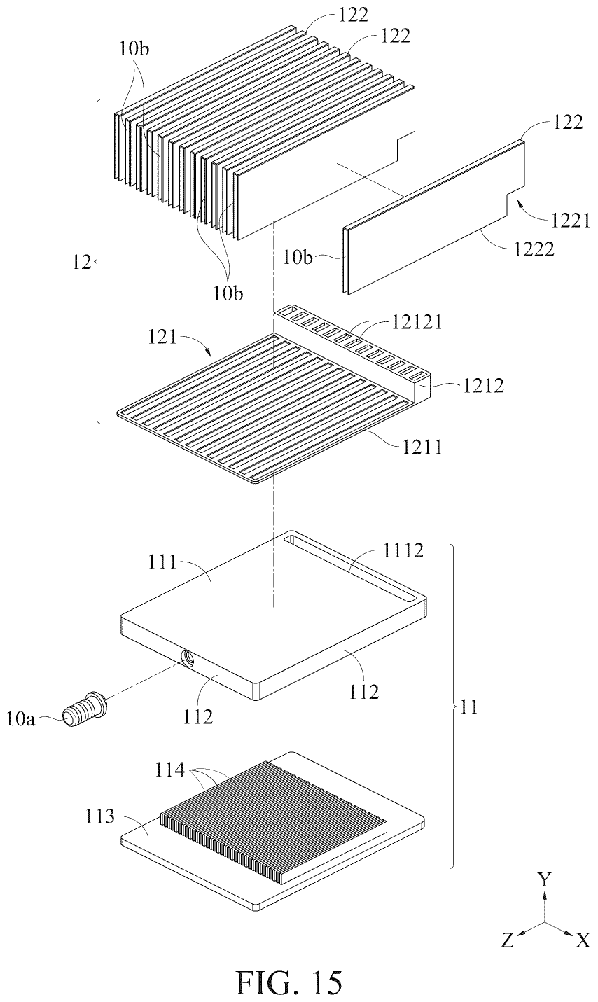

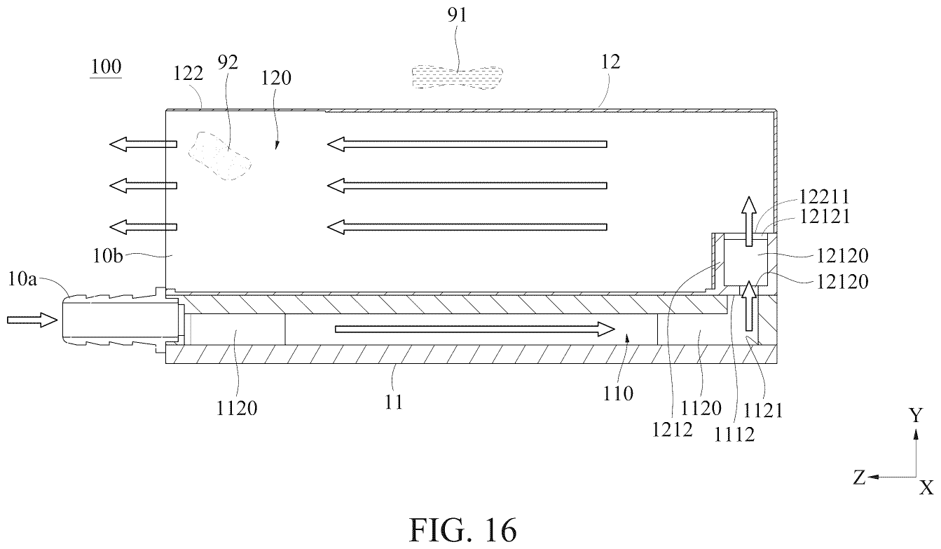

Referring to FIG. 14 to FIG. 16, FIG. 14 is a schematic appearance diagram of the cooling device 100, FIG. 15 is an exploded view of the cooling device 100, and FIG. 16 is a side sectional view of the cooling device 100, in which a side end of each fin 122 is provided with the outlet portion 10b, the cooling module 11 is provided with the inlet portion 10a, and an arrow is used for indicating the flow direction of fluid. In some embodiments, the heat dissipation fin set 12 includes the partition piece 121 and the plurality of fins 122. The partition piece 121 includes the substrate 1211 and the containing portion 1212. The containing portion 1212 is a rectangular frame and extends along the direction of the first axis X as shown in FIG. 14. The containing portion 1212 is positioned at one end of the substrate 1211. The plurality of flow division hole parts 12121 are formed in one side of the containing portion 1212. The partition piece 121 is attached to the cooling module 11. The fins 122 are arranged on the partition piece 121. The outlet portion 10b is provided at the side end of each fin 122. The side end of each fin 122 is not closed, and the outlet portion 10b is a vertical rectangular notch when being viewed from the direction of the third axis Z of FIG. 14 and FIG. 15. The cooling module 11 is provided with the inlet portion 10a.

When the cooling device 100 conducts heat exchange, it can be seen from FIG. 16 that the second heat transfer fluid 92 enters the first cooling channel 110 from the inlet portion 10a of the cooling module 11, the second heat transfer fluid 92 flows to the slit between the heat dissipation plates 114 from the lower-layer fluid collection chamber 1120 on the left side as shown in FIG. 16 to the lower-layer fluid collection chamber 1120 on the right side. Then, the second heat transfer fluid 92 turns and changes the flow direction to the containing portion 1212 above and then flows to the second cooling channel 120 of the heat dissipation fin set 12 at the upper layer, and the second heat transfer fluid 92 flows out from the outlet portion 10b at the side end of each fin 122 on the left side as shown in FIG. 16. The second heat transfer fluid 92 is enabled to flow along the U-shaped (seen from the direction of the first axis X) first cooling channel 110 and the second cooling channel 120 which rotate by 90° anticlockwise, so as to take away heat energy.

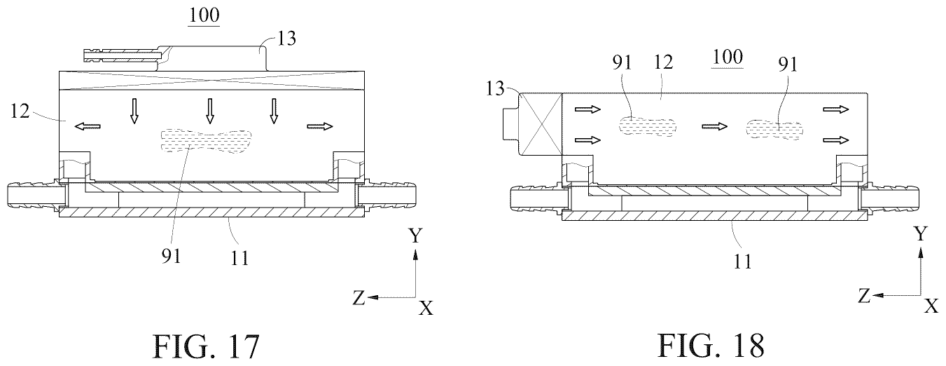

Referring to FIG. 17, FIG. 17 is a side sectional view of the cooling device 100, in which a heat dissipation device 13 is positioned above the heat dissipation fin set 12, and an arrow is used for indicating the flow direction of fluid. In some embodiments, the cooling device 100 further includes the heat dissipation device 13, and the heat dissipation device 13 is a fan for liquid and is positioned above the heat dissipation fin set 12, which is not limited thereto. Referring to FIG. 18, in some embodiments, the cooling device 100 further includes the heat dissipation device 13 positioned at the side end of the heat dissipation fin set 12. An outlet of the heat dissipation device 13 faces toward the heat dissipation fin set 12. As shown in FIG. 17, the heat dissipation device 13 conveys the first heat transfer fluid 91 to the heat dissipation fin set 12 from top to bottom, and the first heat transfer fluid 91 flows out from the two sides of the heat dissipation fin set 12 and takes away the heat source on the heat dissipation fin set 12. As shown in FIG. 18, the heat dissipation device 13 conveys the first heat transfer fluid 91 to the heat dissipation fin set 12 from left to right and takes away the heat source on the heat dissipation fin set 12. Thus, the heat dissipation device 13 is arranged on the heat dissipation fin set 12 to enhance the convection and heat dissipation effects.

In conclusion, according to some embodiments, the cooling device is provided with the heat dissipation fin set above the cooling module, so that the second heat transfer fluid flows and exchanges heat through the first cooling channel in the cooling module and the second cooling channel in the heat dissipation fin set.

What is claimed is:

1. A cooling device, comprising:
a cooling module, wherein a first cooling channel is formed in the cooling module;
a heat dissipation fin set, located on the cooling module and including a plurality of fins, wherein a second cooling channel is formed in the plurality of fins;
an inlet portion, disposed to the heat dissipation fin set or to the cooling module; and
an outlet portion, disposed to the cooling module or to the heat dissipation fin set,
wherein the first cooling channel, the second cooling channel, the inlet portion and the outlet portion are in fluid communication with each other.

2. The cooling device according to claim 1, wherein the heat dissipation fin set includes a partition piece, the partition piece includes a substrate and a plurality of containing portions, each of the plurality of containing portions is positioned on each of two ends of the substrate, a plurality of flow division hole parts are formed in one side of each of the plurality of containing portions, the partition piece is connected to the cooling module, and the plurality of fins are connected to the partition piece.

3. The cooling device according to claim 2, wherein each of the plurality of fins includes a plurality of combination portions and a plurality of open hole parts in fluid communication with the second cooling channel, each of the plurality of containing portions is connected to the corresponding each of the plurality of combination portions, and the plurality of open hole parts of each of the plurality of fins are connected to the plurality of flow division holes of the corresponding each of the plurality of containing portions.

4. The cooling device according to claim 3, wherein each of the plurality of fins includes a connecting portion between the plurality of combination portions of each of the plurality of fins, the partition piece includes a plurality of accommodation portions disposed on the substrate, and the connecting portion of each of the plurality of fins is attached to the corresponding each of the plurality of accommodation portions.

5. The cooling device according to claim 2, wherein the cooling module further includes a bearing plate, a bottom plate, a plurality of side walls and a plurality of heat dissipation plates, the plurality of side walls connected with the bearing plate, and the plurality of heat dissipation plates disposed on the bottom plate, wherein the heat dissipation plates are disposed among the side walls, and a lower-layer fluid collection chamber is formed among the bearing plate, the side walls, and the bottom plate.

6. The cooling device according to claim 5, wherein a communicating hole part is formed in the other side of one of the plurality of the containing portions, the cooling module further includes a connecting hole part formed in the bearing plate, wherein the connecting hole part corresponds to the communicating hole part, and each of the plurality of the containing portions is in fluid communication with the lower-layer fluid collection chamber via the connecting hole part and corresponding communicating hole part.

7. The cooling device according to claim 6, wherein one of the plurality of the containing portions of the partition piece and one of the plurality of the side walls of the cooling module are respectively provided with the inlet portion and the outlet portion, and the inlet portion and the outlet portion are away from the communicating hole part and the connecting hole part and are disposed on the same end of the cooling device.

8. The cooling device according to claim 5, wherein one of the plurality of containing portions of the partition piece and one of the plurality of the side walls of the cooling module are respectively connected to the inlet portion and the outlet portion, and the inlet portion and the outlet portion are respectively disposed on two ends of the cooling device.

9. The cooling device according to claim 8, wherein the partition piece includes a baffle arranged in one of the plurality of the containing portions and an interior part of the containing portion is divided into two upper-layer fluid collection chambers.

10. The cooling device according to claim 9, wherein the other side of one of the plurality of the containing portions is provided with a communicating hole part in fluid communication with one of the upper-layer fluid collection chambers, the cooling module includes a connecting hole part corresponding to the communicating hole part formed in the bearing plate, and the connecting hole part is in fluid communication with one of the upper-layer fluid collection chambers.

11. The cooling device according to claim 10, wherein the inlet portion is provided in one of the plurality of the containing portions and in fluid communication with the other upper-layer fluid collection chamber, the inlet portion is adjacent to the communicating hole part and the connecting hole part, and the outlet portion is remote from the communicating hole part and the connecting hole part.

12. The cooling device according to claim 10, wherein the outlet portion is arranged in one of the plurality of containing portions and in fluid communication with the other upper-layer fluid collection chamber, the outlet portion is adjacent to the communicating hole part and the connecting hole part, and the inlet portion is remote from the communicating hole part and the connecting hole part.

13. The cooling device according to claim 5, wherein the other side of each of the plurality of containing portions is provided with a plurality of communicating hole parts in fluid communication with an interior part of each of the plurality of the containing portions, the cooling module is provided with a plurality of connecting hole parts formed in the bearing plate, and each of the connecting hole parts corresponds to each of the plurality of communicating hole parts and in fluid communication with the interior part of the containing portion.

14. The cooling device according to claim 13, wherein the plurality of side walls of the cooling module are respectively provided with the inlet portion and the outlet portion, and the inlet portion and the outlet portion are respectively located on the two ends of the cooling module.

15. The cooling device according to claim 13, wherein each of the plurality of containing portions of the partition piece is provided with the inlet portion and the outlet portion, and the inlet portion and the outlet portion are respectively disposed on two sides of the partition piece.

16. The cooling device according to claim 1, wherein the heat dissipation fin set includes a partition piece, the partition piece includes a substrate and a containing portion, the containing portion is positioned on one side of the substrate, one side of the containing portion is provided with a plurality of flow division hole parts, the partition piece is attached to the cooling module, the plurality of fins are connected to the partition piece, a side end of each of plurality of fins is provided with the outlet portion, and the cooling module is provided with the inlet portion.

17. An immersion cooling system, comprising:
a container;
a first heat transfer fluid, contained in the container;
an electronic element, positioned in the container;
a cooling device, positioned in the container and being in contact with the electronic element, wherein the cooling device includes:
a cooling module,
a heat dissipation fin set,
an inlet portion, and
an outlet portion,
wherein a first cooling channel is formed in the cooling module, the heat dissipation fin set is located on the cooling module, the heat dissipation fin set includes a plurality of fins, a second cooling channel is formed in the plurality of fins, the inlet portion disposed to the heat dissipation fin set or to the cooling module, the outlet portion disposed to the cooling module or to the heat dissipation fin set, and the first cooling channel, the second cooling channel, the inlet portion and the outlet portion are in fluid communication with each other; and
a second heat transfer fluid, contained in the first cooling channel and the second cooling channel.

18. The immersion cooling system according to claim 17, wherein the heat dissipation fin set includes:
a partition piece including:
a substrate, and
a plurality of containing portions each of the plurality of containing portions is positioned on each of two ends of the substrate,
wherein a plurality of flow division hole parts are formed in one side of each of the plurality of containing portions, the partition piece is connected to the cooling module, the plurality of fins are connected to the partition piece, each of the plurality of fins includes a plurality of combination portions and an open hole part in fluid communication with the second cooling channel, each of the plurality of containing portions is connected to the corresponding each of the plurality of combination portions, the open hole part of each of the plurality of fins is connected to the plurality of flow division hole parts of the corresponding each of the plurality of containing portions, each of the plurality of fins includes a connecting portion between the plurality of combination portions of each of the plurality of fins, the partition piece includes a plurality of accommodation portions disposed on the substrate, the connecting portion of each of the plurality of fins is attached to the corresponding each of the plurality of accommodation portions, the cooling module is provided with a bearing plate and a plurality of side walls connected with the bearing plate, the cooling module includes a bottom plate, a bottom plate, a plurality of side walls and a plurality of heat dissipation plates, the plurality of heat dissipation plates disposed on the bottom plate, wherein the heat dissipation plates are disposed among the side walls, a lower-layer fluid collection chamber is formed among the bearing plate, the side walls, a communicating hole part is formed in the other side of one of the plurality of the containing portions, the cooling module is provided with a connecting hole part formed in the bearing plate, wherein the connecting hole part corresponds to the communicating hole part and each of the plurality of the containing portions is in fluid communication with the lower-layer fluid collection chamber via the connecting hole part and corresponding communicating hole part.

19. An immersion cooling system, comprising:
a first container;
a first heat transfer fluid, contained in the first container;
an electronic element, positioned in the first container;
a cooling device, positioned in the first container and being in contact with the electronic element, wherein the cooling device includes a cooling module, a heat dissipation fin set, an inlet portion and an outlet portion, a first cooling channel is formed in the cooling module, the heat dissipation fin set is located on the cooling module, the heat dissipation fin set includes a plurality of fins, a second cooling channel is formed in the plurality of fins, the inlet portion disposed to the heat dissipation fin set or to the cooling module, the outlet portion disposed to the cooling module or to the heat dissipation fin set, and the first cooling channel, the second cooling channel, the inlet portion and the outlet portion are communicated with each other;
a second container;
a second heat transfer fluid, contained in the second container, the first cooling channel and the second cooling channel;
a plurality of connecting pipes, one end of each of the plurality of connecting pipes being connected to the inlet portion or the outlet portion, and the other end of each of the plurality of connecting pipes being connected to the second container; and
a heat exchange device, includes a guide pipe, a pump and a heat exchange module, the guide pipe being connected to the pump, the heat exchange module and the first container, or being connected to the pump, the heat exchange module and the second container.

20. The immersion cooling system according to claim 19, wherein the heat dissipation fin set includes a partition piece, the partition piece includes a substrate and a plurality of containing portions, each of the plurality of the containing portions is positioned on each of two ends of the substrate, wherein a plurality of flow division hole parts are formed in one side of each of the plurality of containing portions, the partition piece is connected to the cooling module, the plurality of fins are connected to the partition piece, each of the plurality of fins includes a plurality of combination portions and an open hole part in fluid communication with the second cooling channel, each of the plurality of containing portions is connected to the corresponding each of the plurality of combination portions, the open hole part of each of the plurality of fins is connected to the plurality of flow division hole parts of the corresponding each of the plurality of containing portions, each of the plurality of fins includes a connecting portion arranged between the plurality of combination portions of each of the plurality of fins, the partition piece includes a plurality of accommodation portions disposed on the substrate, the connecting portion of each of the plurality of fins is attached to the corresponding each of the plurality of accommodation portions, the cooling module is provided with a bearing plate and a plurality of side walls connected with the bearing plate, the cooling module includes a bottom plate, a bottom plate, a plurality of side walls and a plurality of heat dissipation plates, the plurality of heat dissipation plates disposed on the bottom plate, wherein the heat dissipation plates are disposed among the side walls, a lower-layer fluid collection chamber is formed among the bearing plate, the side walls and the bottom plate, a communicating hole part is formed in the other side of one of the plurality of the containing portions, the cooling module is provided with a connecting hole part formed in the bearing plate, wherein the connecting hole part corresponds to the communicating hole part and each of the plurality of the containing portions is in fluid communication with the lower-layer fluid collection chamber via the connecting hole part and corresponding communicating hole part.
